(19) United States
(12) Patent Application Publication
(10) Pub. No.: US 2024/0237473 A1
(43) Pub. Date: Jul. 11, 2024

(54) DISPLAY DEVICE AND METHOD OF MANUFACTURING DISPLAY DEVICE

(71) Applicant: Samsung Display Co., LTD., Yongin-si (KR)

(72) Inventors: Hyeo Ji KANG, Yongin-si (KR); Oh Jeong KWON, Yongin-si (KR); Tae Ho KIM, Yongin-si (KR); Seung Yeon JEONG, Yongin-si (KR); Mi Hwa LEE, Yongin-si (KR); Hong Yeon LEE, Yongin-si (KR)

(21) Appl. No.: 18/450,202

(22) Filed: Aug. 15, 2023

(30) Foreign Application Priority Data
Jan. 10, 2023 (KR) 10-2023-0003715

(51) Int. Cl. H10K 59/40; H10K 59/12; H10K 59/121; H10K 59/38; H10K 59/80; H10K 71/20

(52) U.S. Cl. CPC H10K 59/40; H10K 59/1201; H10K 59/1213; H10K 59/38; H10K 59/879; H10K 71/233

(57) ABSTRACT

A display device includes: a display part including a light emitting element on a base layer; and a sensor part on the display part and including a conductive pattern including an upper conductive pattern, and an inorganic layer covering the upper conductive pattern, wherein: the inorganic layer includes a first inorganic layer having a first refractive index and a second inorganic layer having a second refractive index less than the first refractive index, and the second inorganic layer is outside the first inorganic layer with respect to the base layer.

### CROSS-REFERENCE TO RELATED APPLICATION

The present application claims priority to and the benefit of Korean Patent Application No. 10-2023-0003715 filed on Jan. 10, 2023, the entire content of is incorporated herein by reference.

### BACKGROUND

### 1. Field

Aspects of some embodiments of the present disclosure relate to a display device and a method of manufacturing the display device.

### 2. Description of the Related Art

As information technology is developed, the importance of a display device, which is a connection medium between a user and information, has been highlighted. The display device may include a light emitting element.

Meanwhile, a structure for improving external visibility may be desirable to the display device. For example, adjusting an external light reflectance for improving external visibility may be desirable.

The above information disclosed in this Background section is only for enhancement of understanding of the background and therefore the information discussed in this Background section does not necessarily constitute prior art.

### SUMMARY

Aspects of some embodiments of the present disclosure may include a display device having relatively improved visibility and a method of manufacturing the display device.

According to some embodiments of the present disclosure, a display device may include a display part including a light emitting element on a base layer, and a sensor part on the display part and including a conductive pattern including an upper conductive pattern, and an inorganic layer covering the upper conductive pattern. According to some embodiments, the inorganic layer may include a first inorganic layer having a first refractive index and a second inorganic layer having a second refractive index less than the first refractive index. According to some embodiments, the second inorganic layer may be outside the first inorganic layer with respect to the base layer.

According to some embodiments, the display device may further include an organic layer including an organic material, on the sensor part, and overlapping the inorganic layer in a plan view.

According to some embodiments, a refractive index of the organic layer may be less than the second refractive index.

According to some embodiments, the inorganic layer may further include a third inorganic layer outside the second inorganic layer and having a third refractive index less than the second refractive index and greater than the refractive index of the organic layer.

According to some embodiments, the organic layer may include a reflection adjust layer including at least one of a dye or a pigment capable of selectively absorbing light of one wavelength band.

According to some embodiments, the reflection adjust layer may include at least one of a group of a tetraazaporphyrin compound, a porphyrin compound, an oxazine compound, a squarylium compound, a triarylmethane compound, a polymethine (cyanine) compound, an anthraquinone compound, a phtalocyanine compound, an azo compound, a perylene compound, an xanthene compound, a diimmonium compound, or a dipyrromethene compound.

According to some embodiments, the organic layer may include a color filter layer that selectively transmits light of one color.

According to some embodiments, the light emitting element may include a first electrode, a second electrode, and an emission layer between the first electrode and the second electrode. According to some embodiments, the display part may further include a low reflection inorganic layer on the second electrode and a thin film encapsulation layer on the low reflection inorganic layer. According to some embodiments, the low reflection inorganic layer may include at least one of a metal or a metal compound.

According to some embodiments, the sensor part may further include a lower conductive pattern and an insulating layer between the lower conductive pattern and the upper conductive pattern. According to some embodiments, the insulating layer may include an organic material.

According to some embodiments, the display device may further include a first sub-pixel forming a first sub-pixel area providing light of a first color, a second sub-pixel forming a second sub-pixel area providing light of a second color, and a third sub-pixel forming a third sub-pixel area providing light of a third color. According to some embodiments, the insulating layer may include a color filter including a colorant that selectively transmits the light of the first color. According to some embodiments, the insulating layer may overlap the first sub-pixel area and may not overlap the second sub-pixel area and the third sub-pixel area in a plan view.

According to some embodiments, at least one layer may be interposed between the first inorganic layer and the organic layer.

According to some embodiments, the first inorganic layer and the second inorganic layer may include materials different from each other.

According to some embodiments, the first inorganic layer and the second inorganic layer may include the same material having compositions different from each other.

According to some embodiments, the display device may further include a pad in a pad area on the base layer. According to some embodiments, the pad may include a first pad layer and a second pad layer on the first pad layer. According to some embodiments, the second pad layer may be on the same layer as the upper conductive pattern.

According to some embodiments of the present disclosure, a display device may include a pixel circuit layer, a light emitting element layer on the pixel circuit layer and including a light emitting element including a first electrode, an emission layer, and a second electrode, a low reflection inorganic layer of the light emitting element, and a thin film encapsulation layer on the low reflection inorganic layer, a sensor part including a first conductive pattern on the thin film encapsulation layer, an insulating layer on the first conductive pattern, a second conductive pattern on the insulating layer, and an inorganic layer on the second conductive pattern, and an upper layer portion on the sensor part and including a reflection adjust layer overlapping the inorganic layer in a plan view. According to some embodiments, the inorganic layer may include a first inorganic layer having a first refractive index and a second inorganic layer having a second refractive index less than the first refractive index. According to some embodiments, the second refractive index may be greater than a refractive index of the reflection adjust layer.

According to some embodiments of the present disclosure, a method of manufacturing a display device may include manufacturing a pixel circuit layer, forming a light emitting element layer on the pixel circuit layer in a display area and forming a first pad layer on the pixel circuit layer in a pad area, patterning a first conductive pattern on the light emitting element layer in the display area, forming an insulating layer on the first conductive pattern in the display area and forming a pad insulating layer in the pad area, patterning a second conductive pattern on the insulating layer in the display area and forming a second pad layer on the pad insulating layer in the pad area, forming an inorganic layer on the second conductive pattern in the display area and forming an inorganic pad layer on the second pad layer in the pad area, and patterning an organic layer on the inorganic layer in the display area. According to some embodiments, the inorganic layer may include a first inorganic layer having a first refractive index and a second inorganic layer having a second refractive index less than the first refractive index.

According to some embodiments, the inorganic layer may be deposited through a chemical vapor deposition (CVD) process.

According to some embodiments, a refractive index of the organic layer may be less than the second refractive index.

According to some embodiments, the organic layer may be a reflection adjust layer or a color filter layer.

According to some embodiments, the method may further include removing the pad inorganic layer in the pad area by using the organic layer as an etching mask.

According to some embodiments of the present disclosure, a display device having relatively improved visibility and a method of manufacturing the display device may be provided.

### BRIEF DESCRIPTION OF THE DRAWINGS

The above and other features of the present disclosure will become more apparent by describing in further detail aspects of some embodiments thereof with reference to the accompanying drawings, in which:

FIG. 1 is a schematic diagram illustrating a display device according to some embodiments;

FIG. 2 is a schematic plan view illustrating a display device according to some embodiments;

FIG. 3 is a schematic cross-sectional view illustrating a stack structure of a display device according to some embodiments;

FIG. 4 is a schematic cross-sectional view illustrating a display part according to some embodiments;

FIG. 5 is a schematic cross-sectional view illustrating a sensor part according to some embodiments;

FIGS. 6 and 7 are schematic cross-sectional views illustrating an inorganic layer according to some embodiments;

FIGS. 8 and 9 are cross-sectional views schematically illustrating a light reflection path in a structure including an inorganic layer and an organic layer according to some embodiments;

FIGS. 10 to 13 are schematic cross-sectional views of a display device according to some embodiments;

FIG. 14 is a schematic cross-sectional view illustrating a stack structure of a display device in each of a display area and a pad area according to some embodiments; and

FIGS. 15 to 19 are schematic cross-sectional views illustrating a method of manufacturing a display device according to some embodiments.

### DETAILED DESCRIPTION

The disclosure may be modified in various manners and have various forms. Therefore, specific embodiments will be illustrated in the drawings and will be described in detail in the specification. However, it should be understood that the disclosure is not intended to be limited to the disclosed specific embodiments, and the disclosure includes all modifications, equivalents, and substitutions within the spirit and technical scope of the disclosure.

Terms of “first”, “second”, and the like may be used to describe various components, but the components should not be limited by the terms. The terms are used only for the purpose of distinguishing one component from another component. For example, without departing from the scope of the disclosure, a first component may be referred to as a second component, and similarly, a second component may also be referred to as a first component. In the following description, the singular expressions include plural expressions unless the context clearly dictates otherwise.

It should be understood that in the present application, a term of “include”, “have”, or the like is used to specify that there is a feature, a number, a step, an operation, a component, a part, or a combination thereof described in the specification, but does not exclude a possibility of the presence or addition of one or more other features, numbers, steps, operations, components, parts, or combinations thereof in advance. In addition, a case where a portion of a layer, a layer, an area, a plate, or the like is referred to as being “on” another portion, it includes not only a case where the portion is “directly on” another portion, but also a case where there is further another portion between the portion and another portion. In addition, in the present specification, when a portion of a layer, a layer, an area, a plate, or the like is formed on another portion, a forming direction is not limited to an upper direction but includes forming the portion on a side surface or in a lower direction. On the contrary, when a portion of a layer, a layer, an area, a plate, or the like is formed “under” another portion, this includes not only a case where the portion is “directly beneath” another portion but also a case where there is further another portion between the portion and another portion.

Aspects of some embodiments of the present disclosure relate to a display device and a method of manufacturing the display device. Hereinafter, a display device and a method of manufacturing the display device according to some embodiments are described with reference to the accompanying drawings.

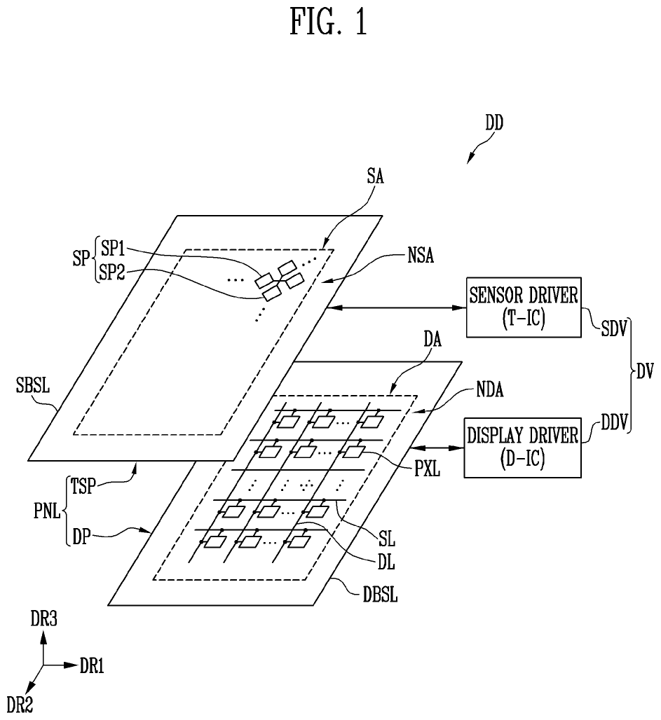

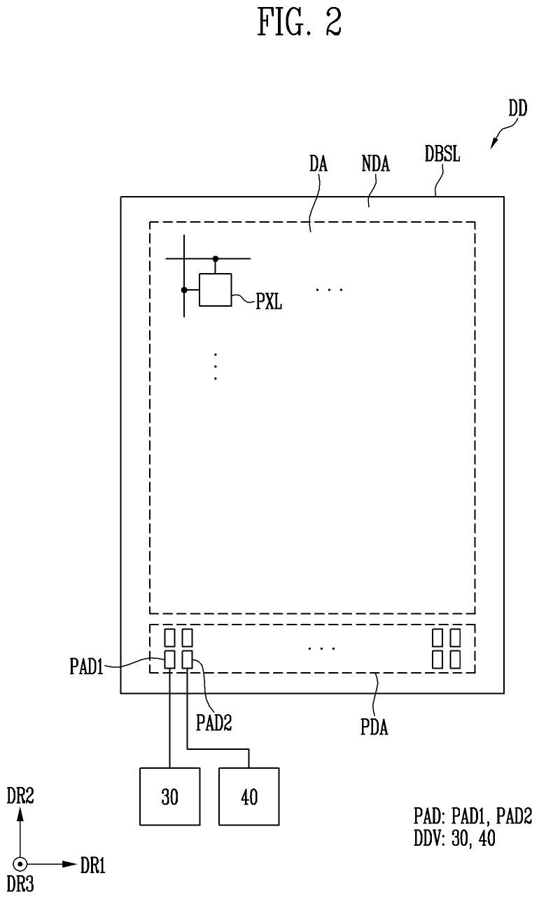

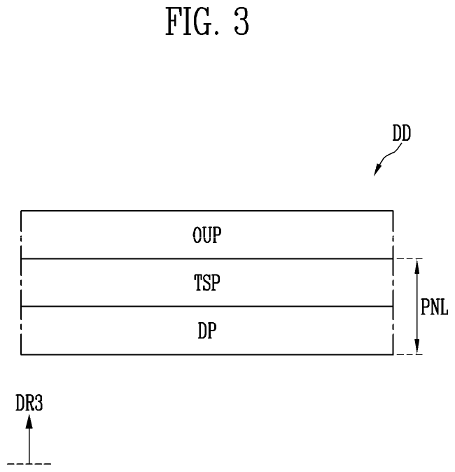

FIG. 1 is a schematic diagram illustrating a display device according to some embodiments. FIG. 2 is a schematic plan view illustrating a display device according to some embodiments. FIG. 3 is a schematic cross-sectional view illustrating a stack structure of a display device according to some embodiments.

Referring to FIGS. 1 to 3, the display device DD is configured to provide (or emit) light. The display device DD may include a panel PNL and a driving circuit part DV for driving the panel PNL. The display device DD may further include an upper layer portion OUP.

The panel PNL may include a display part DP for displaying an image and a sensor part TSP capable of sensing a user input (for example, a touch input). The display part DP may be a display panel. The sensor part TSP may be a sensing panel.

The panel PNL may include a plurality of pixels PXL and sensing electrodes SP. According to some embodiments, the pixels PXL may collectively display images in a display frame period unit. The sensing electrodes SP may sense an input (for example, a touch input) of a user in a sensing frame period unit. A sensing frame period and a display frame period may be independent of each other or may be different from each other. The sensing frame period and the display frame period may be synchronized with each other or may be asynchronous.

The sensor part TSP including the sensing electrodes SP may obtain information on the touch input of the user. According to some embodiments (for example, a mutual capacitance method), the sensing electrodes SP may include a first sensing electrode SP1 providing a first sensing signal and a second sensing electrode SP2 providing a second sensing signal. According to some embodiments, the first sensing electrode SP1 may be a Tx (transmitter) pattern electrode, and the second sensing electrode SP2 may be an Rx (receiver) pattern electrode. According to some embodiments, the information on the touch input (or a touch event) may refer to information including a position or the like of a touch that the user wants to provide.

However, embodiments according to the present disclosure are not limited thereto. For example, according to some embodiments (for example, a self-capacitance method), the sensing electrodes SP may be configured of one type of sensing electrodes without distinction between the first sensing electrode SP1 and the second sensing electrode SP2.

The driving circuit part DV may include a display driver DDV for driving the display part DP and a sensor driver SDV for driving the sensor part TSP.

The display part DP may include a display base layer DBSL and pixels PXL provided on the display base layer DBSL. The pixels PXL may be located in a display area DA.

The display base layer DBSL (or the display device DD) may include the display area DA in which images are displayed and a non-display area NDA outside the display area DA. According to some embodiments, the display area DA may be located in a central area of the display part DP, and the non-display area NDA may be located adjacent to a periphery of the display area DA.

The display base layer DBSL may be a base substrate or a base member for supporting the display device DD. The base layer may be a rigid substrate of a glass material. Alternatively, the base layer may be a flexible substrate of which bending, folding, rolling, or the like is possible. In this case, the base layer may include an insulating material such as a polymer resin such as polyimide. However, embodiments according to the present disclosure are not particularly limited thereto.

Scan lines SL and data lines DL, and the pixels PXL connected to the scan lines SL and the data lines DL are located in the display area DA. The pixels PXL may be configured to be selected by a scan signal of a turn-on level supplied from the scan lines SL, receive a data signal from the data lines DL, and emit light of a luminance corresponding to the data signal. Accordingly, an image corresponding to the data signal is displayed in the display area DA. However, in the disclosure, a structure, a driving method, and the like of the pixels PXL are not particularly limited.

Various lines and/or built-in circuit units connected to the pixels PXL of the display area NDA may be located in the non-display area NDA. For example, a plurality of lines for supplying various power and control signals to the display area DA may be located in the non-display area NDA.

A pad PAD may be located in the non-display area NDA. According to some embodiments, the non-display area NDA may include a pad area PDA in which the pad PAD is located. The pad area PDA may be located on one side of the display area DA. In FIG. 2, the pad area PDA is located adjacent to a lower side of the display area DA, but the disclosure is not limited thereto.

The pad PAD may include a first pad PAD1 and a second pad PAD2. The first pad PAD1 may be a gate pad, and the second pad PAD2 may be a data pad. The first pad PAD1 may be connected to a scan driver 30 of the display driver DDV. A scan signal provided from the scan driver 30 may be transferred to the scan line SL for the pixel PXL via the first pad PAD1. The second pad PAD2 may be connected to a data driver 40 of the display driver DDV. A data signal provided from the data driver 40 may be transferred to the data line DL for the pixel PXL via the second pad PAD2. Positions of the first pad PAD1 and the second pad PAD2 are not particularly limited within the pad area PDA.

The display part DP may output visual information (for example, an image). According to some embodiments, a type/kind of the display part DP is not particularly limited. For example, the display part DP may be implemented as a self-emission type display panel such as an organic light emitting display panel. However, when the display part DP is implemented as a self-emission type, each pixel is not limited to a case in which only an organic light emitting element is included. For example, a light emitting element of each pixel may be formed of an organic light emitting diode, an inorganic light emitting diode, a quantum dot/well light emitting diode, or the like. Alternatively, the display part DP may be implemented as a non-emission type display panel such as a liquid crystal display panel. When the display part DP is implemented as a non-emission type, the display device DD may additionally include a light source such as a backlight unit.

Hereinafter, for convenience of description, the disclosure is described based on embodiments in which the display part DP is implemented as an organic light emitting display panel.

The sensor part TSP includes a sensor base layer SBSL and a plurality of sensing electrodes SP formed on the sensor base layer SBSL. The sensing electrodes SP may be located in a sensing area SA on the sensor base layer SBSL.

The sensor base layer SBSL (or the display device DD) may include a sensing area SA where a touch input or the like may be sensed, and a non-sensing area NSA around the sensing area SA. According to some embodiments, the sensing area SA may be arranged to overlap at least one area of the display area DA. For example, the sensing area SA may be set as an area corresponding to the display area DA (for example, an area overlapping the display area DA), and the non-sensing area NSA may be set as an area corresponding to the non-display area NDA (for example, an area overlapping the non-display area NDA). In this case, when the touch input or the like is provided on the display area DA, the touch input may be detected through the sensor part TSP.

The sensor base layer SBSL may include one or more insulating layers (for example, a first insulating layer INS1 (refer to FIG. 5)). For example, the first insulating layer INS1 for forming the sensor base layer SBSL may be located on the display part DP to form a base for forming the sensing electrodes SP. However, an example for forming the sensor base layer SBSL is not particularly limited.

The sensing area SA may be an area capable of responding to the touch input (that is, an active area of a sensor). The sensing electrodes SP for sensing the touch input or the like may be located in the sensing area SA.

The sensor part TSP may obtain information on an input provided from the user. The sensor part TSP may recognize the touch input. The sensor part TSP may recognize the touch input using a capacitive sensing method. The sensor part TSP may sense the touch input using a mutual capacitance method or may sense the touch input using a self-capacitance method.

According to some embodiments, each of the first sensing electrodes SP1 may extend in a first direction DR1. The first sensing electrodes SP1 may be arranged in a second direction DR2. The second direction DR2 may be different from the first direction DR1. For example, the second direction DR2 may be a direction perpendicular to the first direction DR1. Each of the first sensing electrodes SP1 may have a form in which first cells of a relatively large area and first bridge electrodes of a relatively small area are connected to each other. The first sensing electrodes SP1 may generally have a diamond shape. However, a shape of the first sensing electrodes SP1 is not particularly limited.

According to some embodiments, each of the second sensing electrodes SP2 may extend in the second direction DR2. Each of the second sensing electrodes SP2 may have a form in which second cells of a relatively large area and second bridge electrodes of a relatively small area are connected to each other. The second sensing electrodes SP2 may generally have a diamond shape. However, a shape of the second sensing electrodes SP2 is not particularly limited.

According to some embodiments, the first sensing electrodes SP1 and the second sensing electrodes SP2 may have the same (for example, substantially the same) shape. For example, the first sensing electrodes SP1 which are Tx patterns and the second sensing electrodes SP2 which are Rx patterns may have substantially the same shape, and thus sensing performance of the touch event may be uniformly set within the sensing area SA.

Meanwhile, sensing lines for electrically connecting the sensing electrodes SP to the sensor driver SDV and the like may be located in the non-sensing area NSA of the sensor part TSP.

The driving circuit part DV may include a display driver DDV for driving the display part DP and a sensor driver SDV for driving the sensor part TSP. According to some embodiments, the display driver DDV may include the scan driver 30 and the data driver 40.

The display driver DDV is configured to be electrically connected to the display part DP to drive the pixels PXL. The sensor driver SDV is configured to be electrically connected to the sensor part TSP to drive the sensor part TSP.

The upper layer portion OUP may be generally located at an upper portion of the display device DD. The upper layer portion OUP may be located on the sensor part TSP. Light provided from the display part DP may pass through the upper layer portion OUP and may be output to an outside.

In the present specification, a structure in which a first component is located on the second component may mean a structure in which the first component is spaced apart from the display base layer DBSL than the second component. According to some embodiments, the structure in which the first component is located on the second component may also mean a structure in which the first component is located closer to an outer surface where the sensing area SA and the display area DA are defined than the second component.

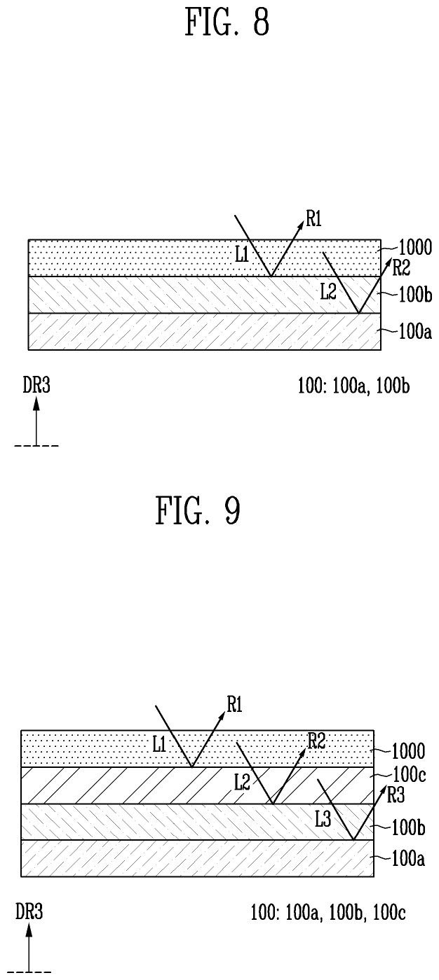

The upper layer portion OUP may protect internal configurations of the display device DD from an external influence. The upper layer portion OUP may include a light blocking layer BM to improve visibility. The upper layer portion OUP may include an organic layer 1000 (refer to FIG. 8) located on an inorganic layer 100 (refer to FIG. 5) to adjust a reflectance. Further details regarding this are described later.

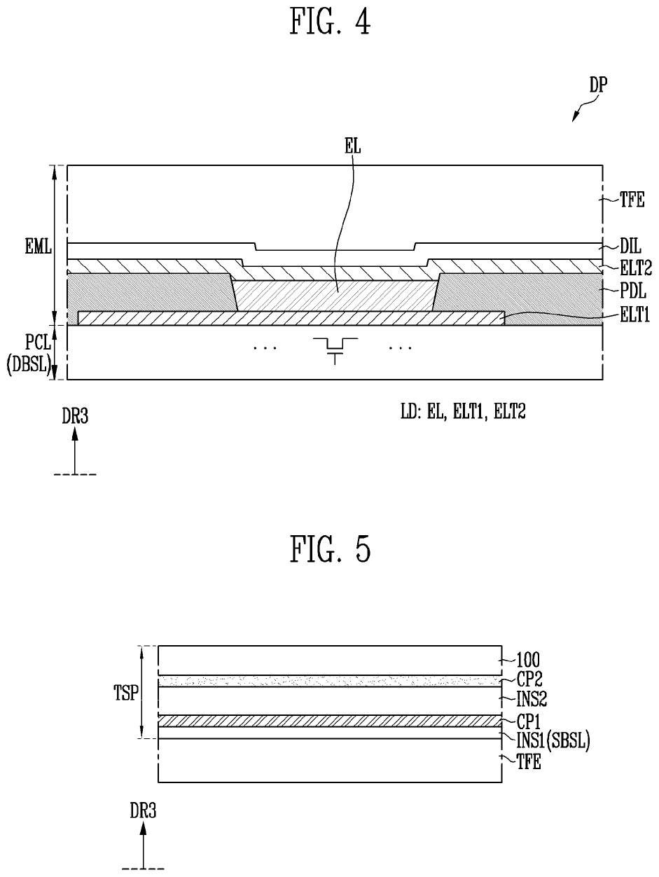

Next, referring to FIG. 4, embodiments of the display part DP are described. FIG. 4 is a schematic cross-sectional view illustrating a display part according to some embodiments.

Referring to FIG. 4, the display part DP may include a pixel circuit layer PCL and a light emitting element layer EML.

The pixel circuit layer PCL may include a pixel circuit for driving light emitting elements LD. The pixel circuit layer PCL may include the display base layer DBSL, conductive layers for forming pixel circuits, and insulating layers located between the conductive layers.

The pixel circuit may include a thin film transistor. The pixel circuit may include a driving transistor. The pixel circuit may be electrically connected to the light emitting elements LD to provide an electrical signal for the light emitting elements LD to emit light.

The light emitting element layer EML may be located on the pixel circuit layer PCL. According to some embodiments, the light emitting element layer EML may include the light emitting element LD, a pixel defining layer PDL, a low reflection inorganic layer DIL, and a thin film encapsulation layer TFE.

The light emitting element LD may be located on the pixel circuit layer PCL. According to some embodiments, the light emitting element LD may include a first electrode ELT1, an emission layer EL, and a second electrode ELT2. According to some embodiments, the emission layer EL may be located in an area defined by the pixel defining layer PDL. The pixel defining layer PDL may be adjacent to a periphery of the emission layer EL. One surface of the emission layer EL may be electrically connected to the first electrode ELT1, and another surface of the emission layer EL may be electrically connected to the second electrode ELT2.

The first electrode ELT1 may be an anode electrode for the emission layer EL, and the second electrode ELT2 may be a common electrode (or a cathode electrode) for the emission layer EL. According to some embodiments, the first electrode ELT1 and the second electrode ELT2 may include a conductive material. For example, the first electrode ELT1 may include a conductive material having a reflective property, and the second electrode ELT2 may include a transparent conductive material, but embodiments according to the present disclosure are not limited thereto.

The emission layer EL may have a multilayer thin film structure including a light generation layer. The emission layer EL may include a hole injection layer for injecting a hole, a hole transport layer having an excellent hole transport property and for increasing a chance of recombination of a hole and an electron by suppressing a movement of an electron that is not combined in the light generation layer, the light generation layer for emitting light by the recombination of the injected electron and hole, a hole blocking layer for suppressing a movement of a hole that is not combined in the light generation layer, an electron transport layer for smoothly transporting the electron to the light generation layer, and an electron injection layer for injecting the electron. The emission layer EL may emit light based on an electrical signal provided from the first electrode ELT1 and the second electrode ELT2.

The pixel defining layer PDL may be located on the pixel circuit layer PCL to define a position where the emission layer EL is arranged. The pixel defining layer PDL may include an organic material. According to some embodiments, the pixel defining layer PDL may include one or more of a group of acrylic resin, epoxy resin, phenol resin, polyamide resin, and polyimide resin. However, embodiments according to the present disclosure are not limited thereto.

The low reflection inorganic layer DIL may be located on the light emitting element LD (for example, the second electrode ELT2). The low reflection inorganic layer DIL may be located between the thin film encapsulation layer TFE and the light emitting element LD.

The low reflection inorganic layer DIL may include an inorganic material. For example, the low reflection inorganic layer DIL may include one or more of a metal or a metal compound. For example, the metal may include one or more of aluminum (Al), silver (Ag), magnesium (Mg), chromium (Cr), titanium (Ti), nickel (Ni), gold (Au), tantalum (Ta), copper (Cu), calcium (Ca), cobalt (Co), iron (Fe), molybdenum (Mo), tungsten (W), platinum (Pt), and ytterbium (Yb). The metal compound may include one or more of a group silicon oxide (SiOx), titanium oxide (TiOx), zirconium oxide (ZrOx), tantalum oxide (TaxOy), hafnium oxide (HfOx), aluminum oxide (AlxOy,) zinc oxide (ZnOx), yttrium oxide (YxOy), beryllium oxide (BeOx), magnesium oxide (MgOx), lead oxide (PbOx), tungsten oxide (WOx), silicon nitride (SiNx), lithium fluoride (LiFx), calcium fluoride (CaFx), magnesium fluoride (MgFx), and cadmium sulfide (CdSx). One or more of the above-described materials may be selected as the low reflection inorganic layer DIL in consideration of a refractive index and an absorption coefficient.

The low reflection inorganic layer DIL may absorb light applied from the outside into the display device DD and reduce an external light reflectance of the display device DD. In addition, the low reflection inorganic layer DIL may reflect the applied light, and light reflected by the low reflection inorganic layer DIL and reflected light reflected by the second electrode ELT2 may interfere with each other and may be eliminated. Accordingly, because the low reflection inorganic layer DIL is included, display quality and visibility of the display device DD may be relatively improved.

The thin film encapsulation layer TFE may be located on the low reflection inorganic layer DIL. The thin film encapsulation layer TFE may offset a step difference generated by the light emitting element LD, the low reflection inorganic layer DIL, and the pixel defining layer PDL. The thin film encapsulation layer TFE may include a plurality of insulating layers covering the light emitting element LD. According to some embodiments, the thin film encapsulation layer TFE may have a structure in which an inorganic layer and an organic layer are alternately stacked.

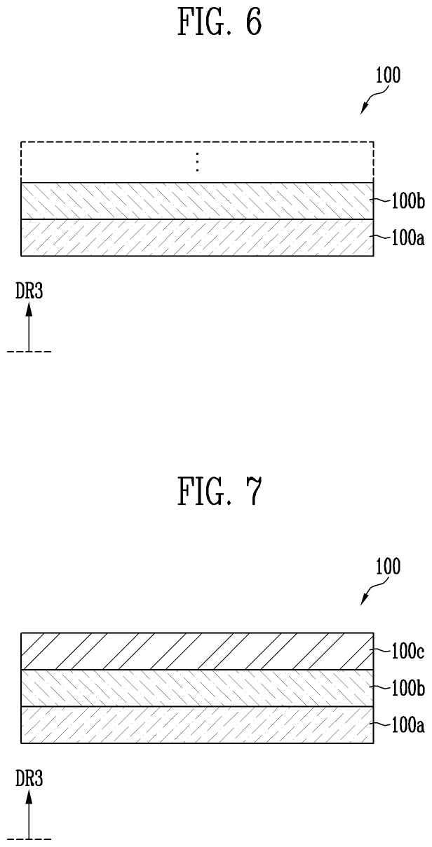

Next, aspects of some embodiments of the sensor part TSP are described with reference to FIGS. 5 to 7. FIG. 5 is a schematic cross-sectional view illustrating a sensor part according to some embodiments. FIGS. 6 and 7 are schematic cross-sectional views illustrating an inorganic layer according to some embodiments.

Referring to FIG. 5, the sensor part TSP may be located on the thin film encapsulation layer TFE. The sensor part TSP may include a first insulating layer INS1, a first conductive pattern CP1, a second insulating layer INS2, a second conductive pattern CP2, and the inorganic layer 100.

According to some embodiments, the first conductive pattern CP1 and the second conductive pattern CP2 may be patterned at one position to form the sensing electrodes SP. For example, a portion of each of the first conductive pattern CP1 and the second conductive pattern CP2 may configure the first sensing electrode SP1, and a portion of the second conductive pattern CP2 may configure the second sensing electrode SP2. However, embodiments according to the present disclosure are not limited thereto.

The first insulating layer INS1 may be located on the thin film encapsulation layer TFE. The first insulating layer INS1 may form the sensor base layer SBSL, and thus may provide an area where the first conductive pattern CP1, the second insulating layer INS2, the second conductive pattern CP2, and the inorganic layer 100 are located.

The first conductive pattern CP1 may be located on the first insulating layer INS1. The second conductive pattern CP2 may be located on the second insulating layer INS2. The first conductive pattern CP1 and the second conductive patterns CP2 may be spaced apart from each other with the second insulating layer INS2 interposed therebetween.

The first conductive pattern CP1 and the second conductive pattern CP2 may include a metal layer of a single layer or multiple layers. The first conductive pattern CP1 and the second conductive pattern CP2 may include at least one of various metal materials including gold (Au), silver (Ag), aluminum (Al), molybdenum (Mo), chromium (Cr), titanium (Ti), nickel (Ni), neodymium (Nd), copper (Cu), or platinum (Pt), or an alloy thereof. According to some embodiments, the first conductive pattern CP1 and the second conductive pattern CP2 may include at least one of various transparent conductive materials including one of a silver nanowire (AgNW), indium tin oxide (ITO), indium zinc oxide (IZO), indium gallium zinc oxide (IGZO), antimony zinc oxide (AZO), indium tin zinc oxide (ITZO), zinc oxide (ZnO), tin oxide (SnO2), carbon nano tube, and/or graphene.

The second insulating layer INS2 may be located on the first conductive pattern CP1. The second insulating layer INS2 may be interposed between the first conductive pattern CP1 and the second conductive pattern CP2. The inorganic layer 100 may be located on the second conductive pattern CP2. According to some embodiments, the second conductive pattern CP2 may be an upper conductive pattern. For example, the second conductive pattern CP2 may be an uppermost conductive layer among conductive layers for forming the sensor part TSP. According to some embodiments, the first conductive pattern CP1 may be a lower conductive pattern. For example, the first conductive pattern CP1 may be a conductive layer located below the second conductive pattern CP2 forming the upper conductive layer (for example, closer to the first insulating layer INS1).

The first insulating layer INS1 may include an inorganic material. The inorganic layer 100 may include an inorganic material. According to some embodiments, the second insulating layer INS2 may include an organic material. The inorganic material may include one or more of a group of silicon nitride (SiNx), silicon oxide (SiOx), silicon oxynitride (SiOxNy), and aluminum oxide (AlOx). The organic material may include one or more of acryl-based resin, methacryl-based resin, polyisoprene, vinyl-based resin, epoxy-based resin, urethane-based resin, cellulose-based resin, siloxane-based resin, polyimide-based resin, polyamide-based resin, and perylene-based resin. However, the disclosure is not limited thereto. According to some embodiments, the second insulating layer INS2 may be selectively located in a partial area and may include a color filter.

Meanwhile, referring to FIGS. 6 and 7, the inorganic layer 100 may include a plurality of layers. For example, the inorganic layer 100 may include at least a first inorganic layer 100a and a second inorganic layer 100b (FIG. 6). According to some embodiments, the inorganic layer 100 may include the first inorganic layer 100a and the second inorganic layer 100b, and may further include a third inorganic layer 100c on the second inorganic layer 100b (FIG. 7).

Each of the inorganic layers forming the inorganic layer 100 may be sequentially stacked along a display direction (for example, the third direction DR3) of the display device DD. For example, the first inorganic layer 100a may be closer to a display base layer DBSL than the second inorganic layer 100b, and the second inorganic layer 100b may be located outside the first inorganic layer 100a. According to some embodiments, the first inorganic layer 100a may contact the second conductive pattern CP2.

Each of the inorganic layers forming the inorganic layer 100 may include one inorganic material. According to some embodiments, the inorganic layers adjacent to each other may include inorganic materials different from each other so that interfaces having different refractive indices are formed.

For example, the first inorganic layer 100a may include a first inorganic material, and the second inorganic layer 100b may include a second inorganic material. According to some embodiments, the third inorganic layer 100c may include a third inorganic material. According to some embodiments, the first inorganic material and the second inorganic material may be different. According to some embodiments, the second inorganic material and the third inorganic material may be different.

However, the disclosure is not limited thereto. According to some embodiments, the inorganic layers adjacent to each other may include the same inorganic material so that interfaces having different refractive indices, and the respective inorganic layers may have different refractive indices because a composition of a material forming each inorganic material is changed. For example, each of the first inorganic layer 100a and the second inorganic layer 100b may include silicon oxide (SiOx), and a ratio of oxygen in the first inorganic layer 100a may be less than that in the second inorganic layer 100b. In another example, each of the first inorganic layer 100a and the second inorganic layer 100b may include silicon nitride (SiNx), and a ratio of nitrogen in the first inorganic layer 100a may be greater than that in the second inorganic layer 100b.

According to some embodiments, the inorganic layer 100 may form a multilayer inorganic layer structure, and the formed inorganic layer structure may be prepared to have a lower refractive index from a lower side to an upper side (for example, an outer side).

For example, the first inorganic layer 100a (for example, the first inorganic material) may have a first refractive index, the second inorganic layer 100b (for example, the second inorganic material) may have a second refractive index, and the third inorganic layer 100c (for example, the third inorganic material) may have a third refractive index. Here, the first refractive index may be greater than the second refractive index. The second refractive index may be greater than the third refractive index.

According to some embodiments, the refractive index of the inorganic layer may be about 1.4 to 2.5. For example, the first refractive index may be 1.8 to 2.0. The second refractive index may be 1.6 to 1.8. The third refractive index may be 1.5 to 1.6. However, embodiments according to the present disclosure are not necessarily limited thereto.

According to some embodiments, each of the layers forming the inorganic layer 100 may have one thickness. For example, each of the layers forming the inorganic layer 100 may have a thickness in a range of 100 Å to 2000 Å. According to some embodiments, the first inorganic layer 100a and the second inorganic layer 100b may have the same thickness as each other. According to some embodiments, the first inorganic layer 100a, the second inorganic layer 100b, and the third inorganic layer 100c may have the same thickness as each other. However, the disclosure is not necessarily limited thereto.

According to some embodiments, the inorganic layer 100 may be formed using various deposition processes. For example, the inorganic layer 100 may be manufactured (or deposited) through a chemical vapor deposition (CVD) process. According to some embodiments, a detailed composition of the inorganic material forming the inorganic layer 100 may be changed by changing a process condition during the CVD process, and thus the refractive index of the inorganic layer 100 may be differently manufactured.

According to some embodiments, the inorganic layer 100 may include an uppermost inorganic layer. For example, when the inorganic layer 100 includes the first inorganic layer 100a and the second inorganic layer 100b, the uppermost inorganic layer may be the second inorganic layer 100b. In another example, when the inorganic layer 100 includes the first inorganic layer 100a, the second inorganic layer 100b, and the third inorganic layer 100c, the uppermost inorganic layer may be the third inorganic layer 100c. According to some embodiments, a refractive index of the uppermost inorganic layer of the inorganic layer 100 may be less than a refractive index of other layers of the inorganic layer 100, and may be greater than a refractive index of other layers adjacent to (or located on) the inorganic layer 100.

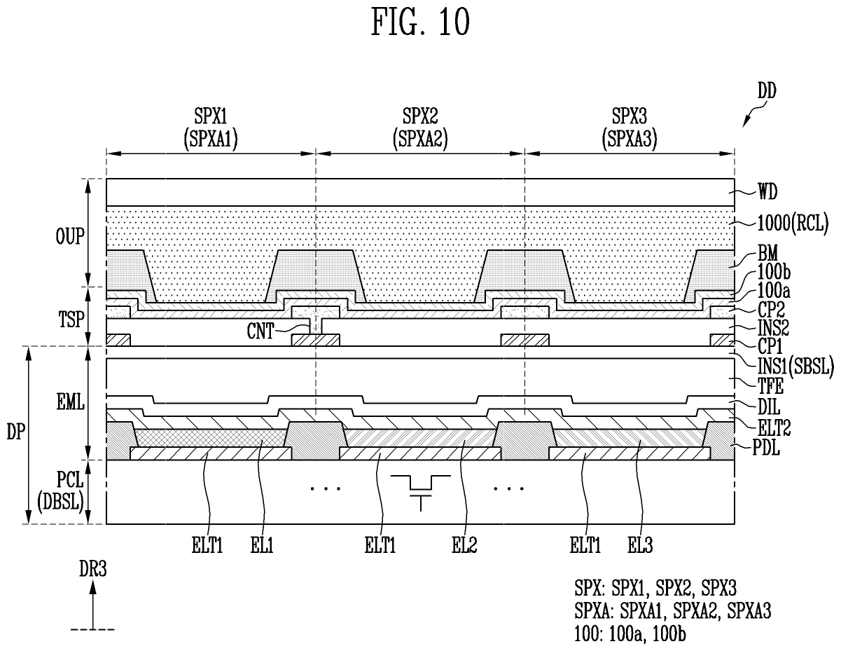

According to some embodiments, the inorganic layer 100 may overlap an area through which light provided from the display part DP is transmitted (for example, the pixel area SPXA (refer to FIG. 10)). According to some embodiments, the inorganic layer 100 may form a multilayer light transmission structure so that an interface having an excessively large refractive index difference between different layers is not formed.

This is described in conjunction with FIGS. 8 and 9. FIGS. 8 and 9 are cross-sectional views schematically illustrating a light reflection path in a structure including an inorganic layer and an organic layer according to some embodiments.

FIG. 8 shows aspects of some embodiments in which the inorganic layer 100 include the first inorganic layer 100a and the second inorganic layer 100b. FIG. 9 shows aspects of some embodiments in which the inorganic layer 100 include the first inorganic layer 100a, the second inorganic layer 100b, and the third inorganic layer 100c.

Referring first to FIG. 8, the organic layer 1000 may be located on the inorganic layer 100. The organic layer 1000 is located on the inorganic layer 100 based on the display direction (for example, the third direction DR3) of the display device DD. Accordingly, the first inorganic layer 100a, the second inorganic layer 100b, and the organic layer 1000 may be sequentially arranged along the third direction DR3. According to some embodiments, one or more layers may be interposed between the organic layer 1000 and the first inorganic layer 100a.

According to some embodiments, the organic layer 1000 may be an upper organic layer. According to some embodiments, the organic layer 1000 may be an outer organic layer.

According to some embodiments, refractive indices of layers through which light passes may sequentially decrease based on the light path (for example, a direction facing the third direction DR3). A refractive index of the organic layer 1000 may be less than that of the inorganic layer 100. According to some embodiments, the first refractive index of the first inorganic layer 100a may be greater than the second refractive index of the second inorganic layer 100b, and the second refractive index of the second inorganic layer 100b may be greater than an upper refractive index of the organic layer 1000.

In this case, the external light reflectance is reduced, and thus practical visibility of the display device DD is remarkably improved. For example, when an interface having a large refractive index difference is formed, the external light reflection may be greatly generated at the corresponding interface, and thus a concern in that visibility is damaged may exist. For example, the organic layer 1000 may be a functional organic layer and may be one or more of a reflection adjust layer RCL, a color filter layer CFL, and an overcoat layer OC.

Experimentally, because a layer including an organic material has a relatively low refractive index, an interface forming a high refractive index difference may be formed, and thus a concern in that a reflectance is damaged may exist. However, according to some embodiments, while the organic layer 1000 forms a functional organic layer, at the same time, the inorganic layer 100 compensates for the refractive index difference due to the organic layer 1000. Therefore, an interface forming a high refractive index difference may not be formed, and an interface formed with a less refractive index difference may be provided. In this case, because the external light reflectance may be relatively reduced, the visibility of the display device DD according to some embodiments may be relatively improved.

For example, light provided from the outside may include first light L1 transmitted through the organic layer 1000. The first light L1 may be reflected at an interface between the organic layer 1000 and the inorganic layer 100. Accordingly, first reflected light R1 may be directed in the display direction (for example, the third direction DR3), and second light L2 may be transmitted. The second light L2 may be reflected at an interface between the second inorganic layer 100b and the first inorganic layer 100a. Accordingly, the second reflected light R2 may be directed in the display direction, and some of light may be transmitted.

Experimentally, when the inorganic layer 100 does not have a multilayer structure, an interface having a large refractive index difference is formed between the inorganic layer 100 and the organic layer 1000, and thus external light reflection may be greatly generated. However, because a plurality of interfaces are formed and the first reflected light R1 and the second reflected light R2 are generated at the interface having a relatively less refractive index difference, external light reflection may be significantly reduced.

Meanwhile, referring to FIG. 9, the inorganic layer 100 according to some embodiments may further include the third inorganic layer 100c. Accordingly, the first inorganic layer 100a, the second inorganic layer 100b, the third inorganic layer 100c, and the organic layer 1000 may be sequentially arranged along the third direction DR3.

Similar to that described above, the inorganic layer 100 further including the third inorganic layer 100c may form a plurality of interfaces, and thus external light reflectance may be relatively improved.

For example, the light provided from the outside may include first light L1 transmitted through the organic layer 1000. The first light L1 may be reflected at an interface between the organic layer 1000 and the inorganic layer 100. Accordingly, first reflected light R1 may be directed in the display direction, and second light L2 may be transmitted. The second light L2 may be reflected at an interface between the third inorganic layer 100c and the second inorganic layer 100b. Accordingly, second reflected light R2 may be directed in the display direction, and third light L3 may be transmitted. The third light L3 may be reflected at an interface between the second inorganic layer 100b and the first inorganic layer 100a. Accordingly, third reflected light R3 may be directed in the display direction, and some of the light may be transmitted.

Next, one or more embodiments of the inorganic layer 100 and a multilayer structure of the display device DD including the inorganic layer 100 are described with reference to FIGS. 10 to 13. A content that may overlap the above-described content is briefly described or is not repeated.

FIGS. 10 to 13 are schematic cross-sectional views of a display device according to some embodiments.

First, a display device DD according to some embodiments is described with reference to FIG. 10.

The display device DD according to some embodiments may include first to third emission layers EL1, EL2, and EL3 emitting light of different colors.

For example, the display device DD may include sub-pixels SPX1, SPX2, and SPX3 each forming a sub-pixel area SPXA. The sub-pixel areas SPXA may include a first sub-pixel area SPXA1 where light of a first color is emitted as an area formed by a first sub-pixel SPX1, a second sub-pixel area SPXA2 where light of a second color is emitted as an area formed by a second sub-pixel SPX2, and a third sub-pixel area SPXA3 where light of a third color is emitted as an area formed by a third sub-pixel SPX3.

A first emission layer EL1 may form a first light emitting element emitting the light of the first color, a second emission layer EL2 may form a second light emitting element emitting the light of the second color, and a third emission layer EL3 may form a third light emitting element emitting the light of the third color.

According to some embodiments, in the sensor part TSP, the first conductive pattern CP1 and the second conductive pattern CP2 may be located on different layers to form a structure of the sensing electrodes SP. The sensor part TSP may include the inorganic layer 100 covering the second conductive pattern CP2 and overlapping the sub-pixel areas SPXA. As described above, the inorganic layer 100 may include the plurality of inorganic layers. This figure shows aspects of some embodiments in which the inorganic layer 100 include the first inorganic layer 100a and the second inorganic layer 100b.

A portion of the first conductive pattern CP1 and a portion of the second conductive pattern CP2 may be electrically connected through a contact portion CNT.

The upper layer portion OUP may be located on the sensor part TSP. The upper layer portion OUP may be located above the first conductive pattern CP1 and the second conductive pattern CP2 forming the sensing electrodes SP.

The upper layer portion OUP may include the light blocking layer BM and the organic layer 1000. According to some embodiments, the organic layer 1000 may be the reflection adjust layer RCL. According to some embodiments, the upper layer portion OUP may further include a window WD located on the reflection adjust layer RCL.

The light blocking layer BM may be covered by the reflection adjust layer RCL and may be located on the sensor part TSP. The light blocking layer BM may be located on the inorganic layer 100.

The light blocking layer BM may overlap the first conductive pattern CP1 in a plan view. The light blocking layer BM may overlap the second conductive pattern CP2 in a plan view. The light blocking layer BM may cover the first conductive pattern CP1 and the second conductive pattern CP2 in a plan view.

The light blocking layer BM may cover the first conductive pattern CP1 and the second conductive pattern CP2 forming the sensing electrodes SP to improve external visibility of the display device DD.

The light blocking layer BM may overlap the pixel defining layer PDL in a plan view. The light blocking layer BM may be located between adjacent sub-pixel areas SPXA in a plan view. The light blocking layer BM may divide adjacent sub-pixel areas SPXA.

The reflection adjust layer RCL may form the organic layer 1000.

The reflection adjust layer RCL may include various materials. According to some embodiments, the reflection adjust layer RCL may include one or more of a dye and a pigment. For example, the reflection adjust layer RCL may include one or more of a tetraazaporphyrin compound, a porphyrin compound, an oxazine compound, a squarylium compound, a triarylmethane compound, a polymethine (cyanine) compound, an anthraquinone compound, a phtalocyanine compound, an azo compound, a perylene compound, an xanthene compound, a diimmonium compound, and a dipyrromethene compound, but embodiments according to the present disclosure are not limited thereto.

The reflection adjust layer RCL may selectively absorb light of one wavelength band. Here, the wavelength band selectively absorbed may include a wavelength band of a non-emission spectrum area that is unintended in the light emitting element layer EML. Accordingly, a color sense of the display device DD may be relatively improved and an external light reflection characteristic may be relatively improved. For example, according to an embodiments, a peak wavelength of a selectively absorbing wavelength band may be in a range of 530 nm to 600 nm. The wavelength band of the non-emission spectrum area may be in a range of 490 nm to 505 nm. According to some embodiments, the wavelength band of the non-emission spectrum area may be 585 nm to 600 nm. However, the disclosure is not necessarily limited thereto.

The reflection adjust layer RCL may offset a step different due to formation of the light blocking layer BM.

The window WD may be located above the reflection adjust layer RCL. The window WD may be a protection member located above the display device DD and may be a substantially transparent light-transmittance member. The window WD may have a multilayer structure selected from a group of a glass substrate, a plastic layer, and a plastic substrate. The window WD may include a rigid or flexible base, and a material for forming the window WD is not particularly limited.

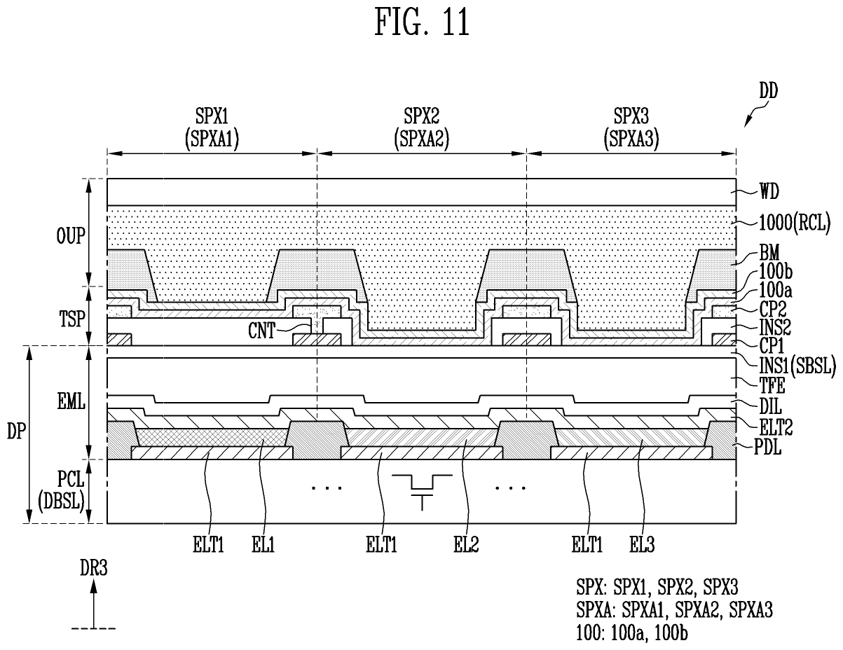

Next, referring to FIG. 11, the display device DD including the inorganic layer 100 according to some embodiments is described.

Referring to FIG. 11, the display device DD according to some embodiments is different from the display device DD described with reference to FIG. 10 in that the second insulating layer INS2 includes a color filter that selectively transmits the color of the light emitted from the first sub-pixel SPX1, and the second insulating layer INS2 is not located in at least a portion of the second sub-pixel area SPXA2 and the third sub-pixel area SPXA3.

For example, the second insulating layer INS2 may include a color filter including a colorant that selectively transmits the light of the first color, may overlap the first sub-pixel area SPXA1 of the first sub-pixel SPX1 that provides the light of the first color, may not overlap at least a portion of the second sub-pixel area SPXA2 of the second sub-pixel SPX2 that provides the light of the second color, and may not overlap at least a portion of the third sub-pixel area SPXA3 of the third sub-pixel SPX3 that provides the light of the third color. According to some embodiments, the light reflection characteristic may be optimized for each color by selectively arranging the color filter in the sub-pixel SPX of some colors among the sub-pixels SPX.

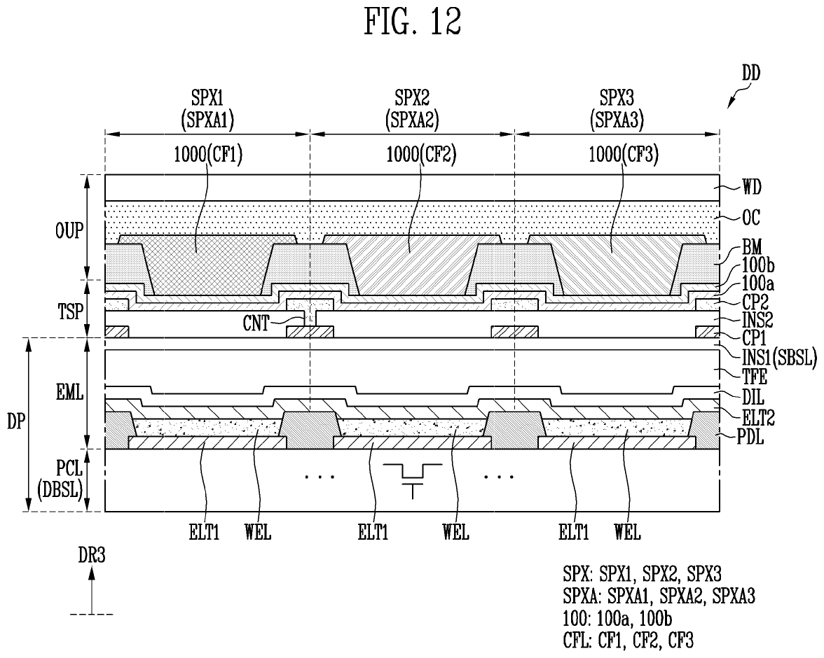

Next, the display device DD including the inorganic layer 100 according to some embodiments is described with reference to FIG. 12.

Referring to FIG. 12, the display device DD according to some embodiments may include white emission layers WEL emitting the same white light as each other. For example, the above-described emission layer EL may be the white emission layer WEL configured to emit white light.

The white emission layer WEL may be located in each of the first to third sub-pixels SPX1, SPX2, and SPX3. According to some embodiments, the display device DD (for example, the upper layer portion OUP) may further include the color filter layer CFL. The color filter layer CFL may include color filters CF1, CF2, and CF3. According to some embodiments, white light may be emitted, the color filters CF1, CF2, and CF3 corresponding to the respective colors of the first to third sub-pixels SPX1, SPX2, and SPX3 may be located, and thus a full-color image may be displayed.

According to some embodiments, the color filters CF1, CF2, and CF3 may form the organic layer 1000.

A first color filter CF1 may overlap the first sub-pixel area SPXA1 in a plan view as a color filter for forming the first sub-pixel SPX1. The first color filter CF1 may selectively transmit the light of the first color. The first color filter CF1 may include a red color filter material as a red color filter.

A second color filter CF2 may overlap the second sub-pixel area SPXA2 in a plan view as a color filter for forming the second sub-pixel SPX2. The second color filter CF2 may selectively transmit the light of the second color. The second color filter CF2 may include a green color filter material as a green color filter.

The third color filter CF3 may overlap the third sub-pixel area SPXA3 in a plan view as a color filter for forming the third sub-pixel SPX3. The third color filter CF3 may selectively transmit the light of the third color. The third color filter CF3 may include a blue color filter material as a blue color filter.

According to some embodiments, the color filters CF1, CF2, and CF3 may form the organic layer 1000. For example, the color filters CF1, CF2, and CF3 may have a refractive index less than that of the inorganic layer 100. The overcoat layer OC may be formed on the color filter layer CFL.

According to some embodiments, the first to third color filters CF1, CF2, and CF3 may overlap on a plane to form the light blocking layer BM. In this case, because the number of masks is relatively reduced, a process cost may be relatively reduced.

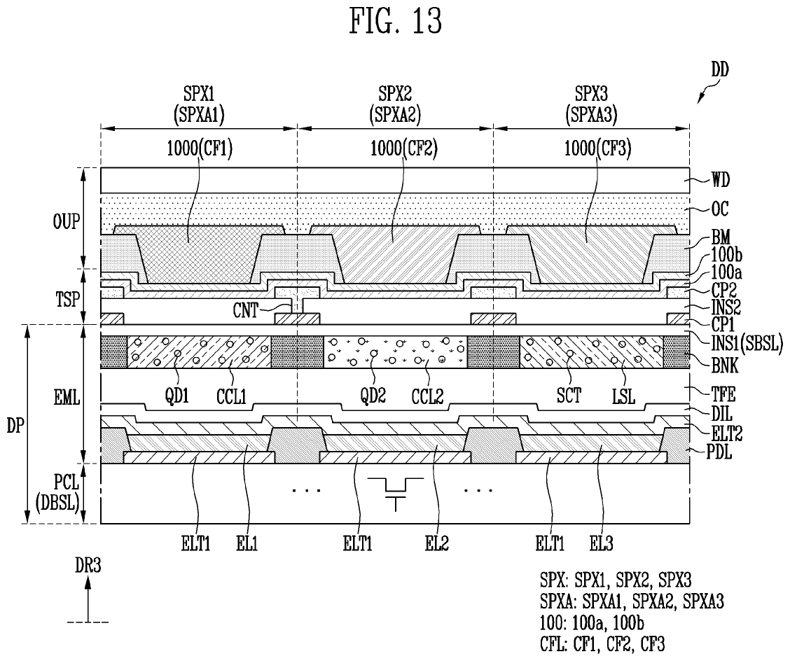

Next, referring to FIG. 13, the display device DD including the inorganic layer 100 according to some embodiments is described.

Referring to FIG. 13, the display device DD according to some embodiments is different from the display device DD described above with reference to FIG. 12, in that the display device DD according to the embodiments illustrated with respect to FIG. 13 includes the first to third emission layers EL1, EL2, and EL3 formed in the respective first to third sub-pixels SPX1, SPX2, and SPX3, and further includes the color conversion layers CCL1 and CCL2.

For example, in accordance with the display device DD according to some embodiments, the color filters CF1, CF2, and CF3 corresponding to the respective colors of the first to third sub-pixels SPX1, SPX2, and SPX3, the color conversion layers CCL1 and CCL2, and a scattering layer LSL may be located, and thus a full-color image may be displayed.

The color conversion layers CCL1 and CCL2 may be configured to change a wavelength of light. The color conversion layers CCL1 and CCL2 and the scattering layer LSL may be located on the light emitting element layer EML. The color conversion layers CCL1 and CCL2 and the scattering layer LSL may be located below the color filters CF1, CF2, and CF3. The color conversion layers CCL1 and CCL2 and the scattering layer LSL may be located between the color filters CF1, CF2, and CF3 and the light emitting element layer EML. The color conversion layers CCL1 and CCL2 and the scattering layer LSL may be located (or patterned) in an area surrounded by a bank BNK protruding in a thickness direction (for example, the third direction DR3) of the display base layer DBSL.

A first color conversion layer CCL1 may include first color conversion particles that convert the light of the third color (for example, blue) emitted from a blue emission layer BEL into the light of the first color (for example, red). For example, the first color conversion layer CCL1 may include a plurality of first quantum dots QD1 dispersed in a predetermined matrix material such as a base resin. The first quantum dot QD1 may emit the red light by absorbing the blue light and shifting a wavelength according to an energy transition.

The second color conversion layer CCL2 may include second color conversion particles that convert the light of the third color (for example, blue) emitted from the blue emission layer BEL into the light of the second color (for example, green). For example, the second color conversion layer CCL2 may include a plurality of second quantum dots QD2 dispersed in a predetermined matrix material such as a base resin. The second quantum dot QD2 may emit the green light by absorbing the blue light and shifting a wavelength according to an energy transition.

According to some embodiments, an absorption coefficient of the first quantum dot DQ1 and the second quantum dot QD2 may be increased by causing the blue light having a relatively short wavelength in a visible ray region to be incident to each of the first quantum dot QD1 and the second quantum dot QD2. Accordingly, efficiency of light emitted from the first sub-pixel SPX1 and the second sub-pixel SPX2 may be improved and excellent color reproducibility may be secured.

The scattering layer LSL may be provided to efficiently use the light of the third color (or blue) emitted from the blue emission layer BEL. For example, the scattering layer LSL may include a scattering body SCT. For example, the scattering body SCT of the scattering layer LSL may include one or more of barium sulfate (BaSO4), calcium carbonate (CaCO3), titanium oxide (TiO2), silicon oxide (SiO2), aluminum oxide (Al2O3), zirconium oxide (ZrO2), and zinc oxide (ZnO). Meanwhile, the scattering body SCT may be located in the third sub-pixel SPX3, and may also be selectively included in the first color conversion layer CCL1 or the second color conversion layer CCL2. According to some embodiments, the scattering body SCT may be omitted, and thus the scattering layer LSL formed of a transparent polymer may be provided.

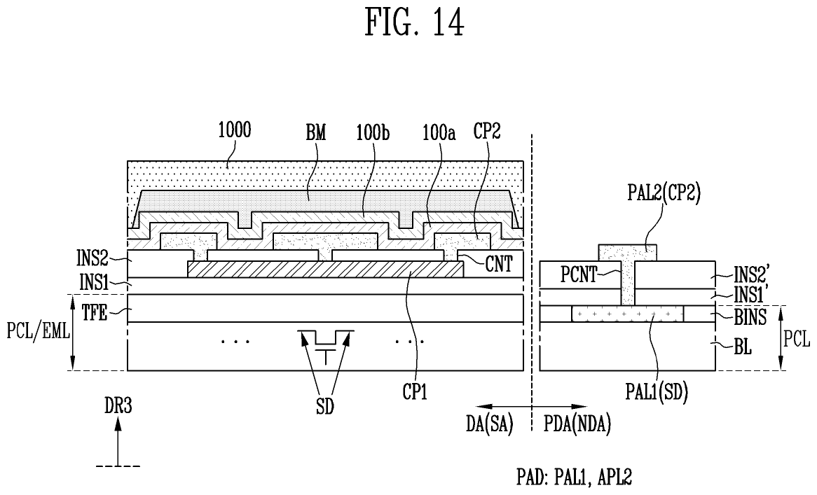

Next, referring to FIG. 14, a stack structure of the display area DA (or the sensing area SA) and the pad area PDA (or the non-display area NDA) is described. A content that may overlap the above-described content is briefly described or is not repeated.

FIG. 14 is a schematic cross-sectional view illustrating a stack structure of a display device in each of a display area and a pad area according to some embodiments. FIG. 14 shows aspects of embodiments in which the inorganic layer 100 includes the first inorganic layer 100a and the second inorganic layer 100b.

Referring to FIG. 14, the stack structure in the display area DA and the stack structure in the pad area PDA may include one or more layers formed in the same process. According to some embodiments, at least a portion of electrodes in the pad area PDA may be pads PAD, and the pad PAD may include a first pad layer PAL1 and a second pad layer PAL2. The pad PAD may have one or more multilayer structures, and the number of layers for forming the pad PAD is not particularly limited.

The pad PAD may be electrically connected to the line in the pixel circuit layer PCL through one or more lines formed between the display area DA and the non-display area NDA. For example, the first pad layer PAL1 may be electrically connected to the lines (for example, the data line DL and the like) in the pixel circuit layer PCL.

According to some embodiments, in the display area DA, the first insulating layer INS1, the first conductive pattern CP1, the second insulating layer INS2, the second conductive pattern CP2, the first inorganic layer 100a, the second inorganic layer 100b, the light blocking layer BM, and the organic layer 1000 may be sequentially located on the thin film encapsulation layer TFE. The first conductive pattern CP1 and the second conductive pattern CP2 may be electrically connected through the contact portion CNT.

According to some embodiments, a lower layer BL on which the pad PAD is located may be formed in the pad area PDA. The lower layer BL may include one or more layers forming the pixel circuit layer PCL. For example, the lower layer BL may include one or more layers located below a transistor electrode layer SD (for example, a source/drain electrode layer) for forming the pixel circuit of the pixel circuit layer PCL.

The first pad layer PAL1 may be located on the lower layer BL. The first pad layer PAL1 may be formed in the same process and may include the same material as the transistor electrode layer SD formed in the display area DA.

A lower insulating layer BINS may be located on the lower layer BL, and the lower insulating layer BINS may expose the first pad layer PAL1. The lower insulating layer BINS may be formed in the same process and may include the same material as one or more layers formed between the first insulating layer INS1 and the transistor electrode layer SD in the display area DA.

A first pad insulating layer INS1′ and a second pad insulating layer INS2′ may be located on the first pad layer PAL1 and the lower insulating layer BINS. The first pad insulating layer INS1′ may be formed in the same process and may include the same material as the first insulating layer INS1 in the display area DA. The second pad insulating layer INS2′ may be formed in the same process and may include the same material as the second insulating layer INS2 in the display area DA.

The second pad layer PAL2 may be located on the second pad insulating layer INS2′. The second pad layer PAL2 may be formed in the same process and may include the same material as the second conductive pattern CP2 formed in the display area DA. The second pad layer PAL2 may be located on the same layer as the second conductive pattern CP2 (for example, the upper conductive pattern) located in the display area DA.

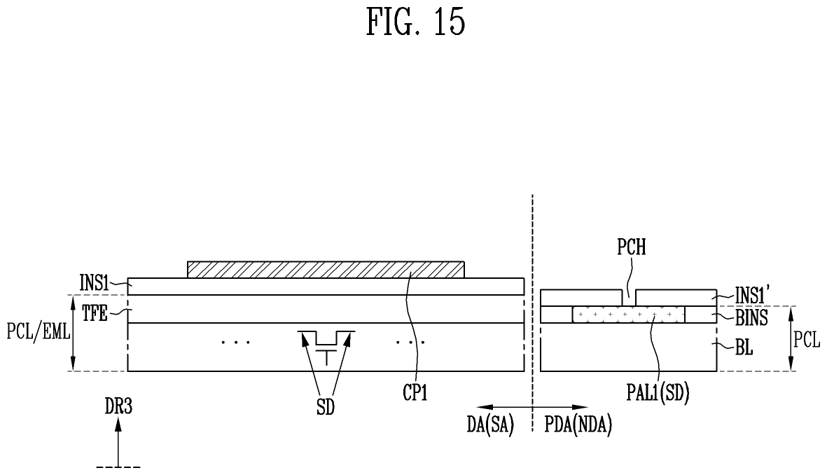

Next, a method of manufacturing the display device DD according to some embodiments is described with reference to FIGS. 15 to 19. A content that may overlap the above-described content is briefly described or is not repeated.

FIGS. 15 to 19 are schematic cross-sectional views illustrating a method of manufacturing a display device according to some embodiments. FIGS. 15 to 19 may illustrate a schematic manufacturing method for a cross-sectional structure of the display device DD described above with reference to FIG. 14. For example, FIGS. 15 to 19 may illustrate a manufacturing method of stack structures of a portion of the display area DA and a portion of the pad area PDA.

Referring to FIG. 15, the pixel circuit layer PCL may be manufactured (or formed) in the display area DA and the pad area PDA, and the light emitting element layer EML may be formed on the pixel circuit layer PCL in the display area DA. In addition, the first insulating layer INS1 may be located in the display area DA, and the first pad insulating layer INS1′ may be located in the pad area PDA. The first conductive pattern CP1 may be patterned on the first insulating layer INS1 in the display area DA.

In the present step, the pixel circuit layer PCL may be manufactured (or formed) by patterning a conductive layer (or a metal layer), an inorganic material, or an organic material by performing a process using a general mask. The lower layer BL may be formed in the same process as some layers of the pixel circuit layer PCL in the display area DA. According to some embodiments, the transistor electrode layer SD may be formed to form the pixel circuit in the display area DA, and the first pad layer PAL1 may be formed on the lower layer BL in the same process. After the first pad layer PAL1 is formed, the lower insulating layer BINS exposing the first pad layer PAL1 may be patterned.

In the present step, the light emitting element layer EML including the light emitting elements LD may be located on the pixel circuit layer PCL. Layers for forming the light emitting elements LD may be manufactured using one deposition process. After forming the light emitting elements LD, the thin film encapsulation layer TFE may be formed.

In the present step, the first insulating layer INS1 may be located on the thin film encapsulation layer TFE in the display area DA, and the first pad insulating layer INS1′ may be patterned in the same process. The first pad insulating layer INS1′ may be patterned to form a pad contact hole PCH exposing the first pad layer PAL1.

In the present step, the first conductive pattern CP1 may be patterned on the first insulating layer INS1 in the display area DA. According to some embodiments, a conductive layer corresponding to the first conductive pattern CP1 may not be formed in the pad area PDA.

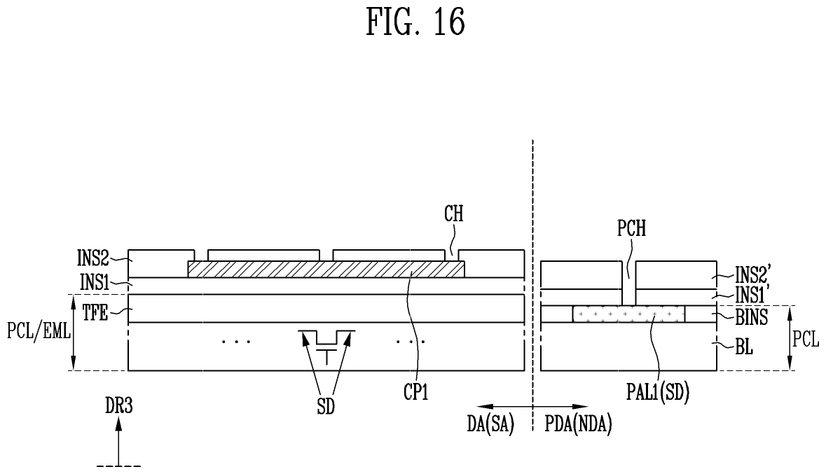

Referring to FIG. 16, the second insulating layer INS2 may be patterned in the display area DA, and the second pad insulating layer INS2′ may be patterned in the pad area PDA.

In the present step, the second insulating layer INS2 and the second pad insulating layer INS2′ may be formed in the same process.

In the present step, the second insulating layer INS2 may form a contact hole CH exposing the first conductive pattern CP1, and the second pad insulating layer INS2′ may form the pad contact hole PCH exposing the first pad layer PAL1.

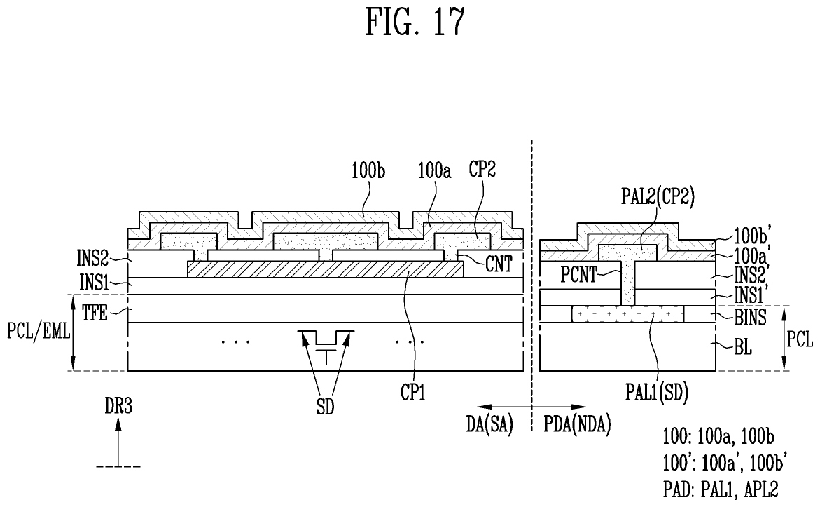

Referring to FIG. 17, the second conductive pattern CP2 may be patterned in the display area DA, and the inorganic layer 100 may be formed on the second conductive pattern CP2. The second pad layer PAL2 may be patterned in the pad area PDA, and a pad inorganic layer 100′ may be formed (or deposited) on the second pad layer PAL2.

In the present step, the second conductive pattern CP2 may be patterned, and the first conductive pattern CP1 and the second conductive pattern CP2 may form the sensing electrode SP.

In the present step, the second pad layer PAL2 in the pad area PDA may be formed in the same process as the second conductive pattern CP2 in the display area DA. A portion of a conductive material for forming the second pad layer PAL2 may be provided in the pad contact hole PCH, and thus a pad contact portion PCNT electrically connecting the second pad layer PAL2 and the first pad layer PAL1 may be manufactured.

In the present step, the inorganic layer 100 in the display area DA and the pad inorganic layer 100′ in the pad area PDA may be formed in the same process. For example, the first inorganic layer 100a in the display area DA and a first inorganic pad layer 100a′ in the pad area PDA may be formed in the same process. The second inorganic layer 100b in the display area DA and a second inorganic pad layer 100b′ in the pad area PDA may be formed in the same process.

In the present step, the inorganic layer 100 and the pad inorganic layer 100′ may be formed through a CVD process. However, the disclosure is not necessarily limited thereto.

According to some embodiments, the first inorganic layer 100a and the second inorganic layer 100b may include different materials to have different refractive indices. The second inorganic layer 100b may have a refractive index less than that of the first inorganic layer 100a. According to some embodiments, the first inorganic layer 100a and the second inorganic layer 100b may have the same material and the materials included in the respective first inorganic layer 100a and second inorganic layer 100b may have different compositions so that the first inorganic layer 100a and the second inorganic layer 100b have different refractive indices.

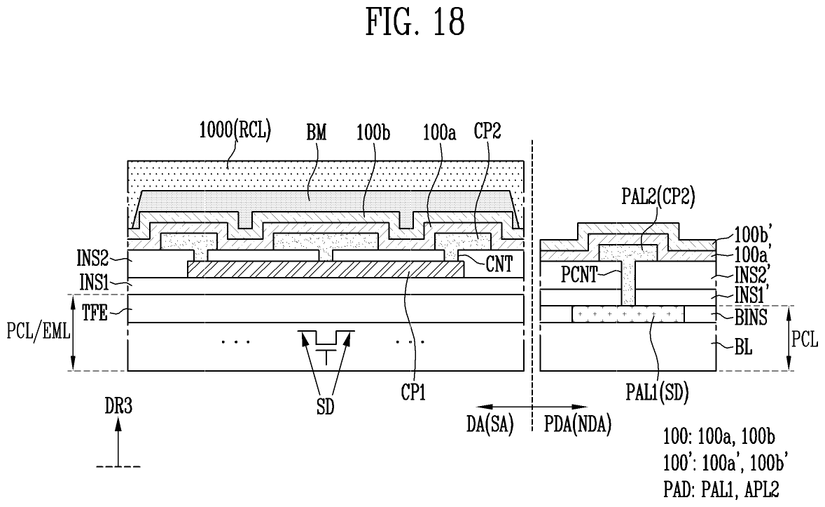

Referring to FIG. 18, the light blocking layer BM may be located on the inorganic layer 100 in the display area DA, and the organic layer 1000 may be patterned (or located) on the inorganic layer 100 to cover the light blocking layer BM.

In the present step, the light blocking layer BM may be patterned to overlap the first conductive pattern CP1 and the second conductive pattern CP2, and the organic layer 1000 may be deposited. According to some embodiments, as described above, the organic layer 1000 may be the reflection adjust layer RCL, the color filter layer CFL, or the overcoat layer OC. For example, in the present step, the light blocking layer BM and the reflection adjust layer RCL may be located on the inorganic layer 100. According to another example, in the present step, the light blocking layer BM, the color filter layer CFL, and the overcoat layer OC may be located on the inorganic layer 100. According to another example, in the present step, the color filter layer CFL and the overcoat layer OC may be located on the inorganic layer 100, and the first to third color filters CF1, CF2, and CF3 forming the color filter layer CFL may overlap on a plane to form the light blocking layer BM.

In the present step, the light blocking layer BM and the organic layer 1000 may not be located in the pad area PDA.

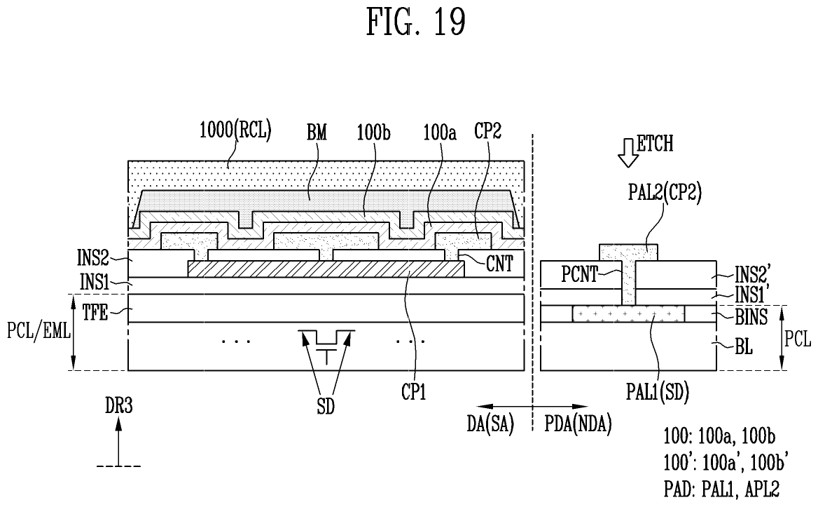

Referring to FIG. 19, the pad inorganic layer 100′ may be removed in the pad area PDA.

In the present step, the pad inorganic layer 100′ may be removed, and thus the second pad layer PAL2 may be exposed. According to some embodiments, the organic layer 1000 may be used as an etching mask for removing the pad inorganic layer 100′. For example, the organic layer 1000 may be located in the display area DA without being located in the pad area PDA, and the pad inorganic layer 100′ may be removed in an area where the organic layer 1000 is not located.

Thereafter, according to some embodiments, the pads PAD may be electrically connected to a conductive structure (for example, a chip-on layer or the like) electrically connected to the driving circuit part DV, an additional layer (for example, the window WD or the like) covering the display area DA and the pad area PDA may be located, and thus the display device DD according to some embodiments may be provided.

As described above, although aspects of some embodiments of the present disclosure have been described with reference to some embodiments above, those skilled in the art or those having a common knowledge in the art will understand that the disclosure may be variously modified and changed without departing from the spirit and technical area of the disclosure described in the claims which will be described later.

Therefore, the technical scope of embodiments according to the present disclosure should not be limited to the contents described in the detailed description of the specification, but should be defined by the claims, and their equivalents.

What is claimed is:

1. A display device comprising:
a display part including a light emitting element on a base layer; and
a sensor part on the display part and including a conductive pattern including an upper conductive pattern, and an inorganic layer covering the upper conductive pattern,
wherein:
the inorganic layer includes a first inorganic layer having a first refractive index and a second inorganic layer having a second refractive index less than the first refractive index, and
the second inorganic layer is outside the first inorganic layer with respect to the base layer.

2. The display device according to claim 1, further comprising:
an organic layer including an organic material on the sensor part, and overlapping the inorganic layer in a plan view.

3. The display device according to claim 2, wherein a third refractive index of the organic layer is less than the second refractive index.

4. The display device according to claim 2, wherein the inorganic layer further includes a third inorganic layer outside the second inorganic layer and having a third refractive index less than the second refractive index and greater than a fourth refractive index of the organic layer.

5. The display device according to claim 2, wherein the organic layer includes a reflection adjust layer including at least one of a dye or a pigment capable of selectively absorbing light of one wavelength band.

6. The display device according to claim 5, wherein the reflection adjust layer includes at least one of a group of a tetraazaporphyrin compound, a porphyrin compound, an oxazine compound, a squarylium compound, a triarylmethane compound, a polymethine (cyanine) compound, an anthraquinone compound, a phtalocyanine compound, an azo compound, a perylene compound, an xanthene compound, a diimmonium compound, or a dipyrromethene compound.

7. The display device according to claim 2, wherein the organic layer includes a color filter layer configured to selectively transmit light of one color.

8. The display device according to claim 1, wherein the light emitting element includes a first electrode, a second electrode, and an emission layer between the first electrode and the second electrode,
the display part further includes a low reflection inorganic layer on the second electrode and a thin film encapsulation layer on the low reflection inorganic layer, and
the low reflection inorganic layer includes at least one of a metal or a metal compound.

9. The display device according to claim 1, wherein the sensor part further includes a lower conductive pattern and an insulating layer between the lower conductive pattern and the upper conductive pattern, and
the insulating layer includes an organic material.

10. The display device according to claim 9, further comprising:
a first sub-pixel forming a first sub-pixel area configured to provide light of a first color;
a second sub-pixel forming a second sub-pixel area configured to provide light of a second color; and
a third sub-pixel forming a third sub-pixel area configured to provide light of a third color,
the insulating layer includes a color filter including a colorant configured to selectively transmit the light of the first color, and
the insulating layer overlaps the first sub-pixel area and does not overlap the second sub-pixel area and the third sub-pixel area in a plan view.

11. The display device according to claim 2, wherein at least one layer is interposed between the first inorganic layer and the organic layer.

12. The display device according to claim 1, wherein the first inorganic layer and the second inorganic layer include materials different from each other.

13. The display device according to claim 1, wherein the first inorganic layer and the second inorganic layer include a same material having compositions different from each other.

14. The display device according to claim 1, further comprising:
a pad in a pad area on the base layer,
wherein:
the pad includes a first pad layer and a second pad layer on the first pad layer, and
the second pad layer is on a same layer as the upper conductive pattern.

15. A display device comprising:
a pixel circuit layer;
a light emitting element layer on the pixel circuit layer and including a light emitting element including a first electrode, an emission layer, and a second electrode, a low reflection inorganic layer of the light emitting element, and a thin film encapsulation layer on the low reflection inorganic layer;
a sensor part including a first conductive pattern on the thin film encapsulation layer, an insulating layer on the first conductive pattern, a second conductive pattern on the insulating layer, and an inorganic layer on the second conductive pattern; and
an upper layer portion on the sensor part and including a reflection adjust layer overlapping the inorganic layer in a plan view,
wherein:
the inorganic layer includes a first inorganic layer having a first refractive index and a second inorganic layer having a second refractive index less than the first refractive index, and
the second refractive index is greater than a third refractive index of the reflection adjust layer.

16. A method of manufacturing a display device, the method comprising:
manufacturing a pixel circuit layer;
forming a light emitting element layer on the pixel circuit layer in a display area and forming a first pad layer on the pixel circuit layer in a pad area;
patterning a first conductive pattern on the light emitting element layer in the display area;
forming an insulating layer on the first conductive pattern in the display area and forming a pad insulating layer in the pad area;
patterning a second conductive pattern on the insulating layer in the display area and forming a second pad layer on the pad insulating layer in the pad area;
forming an inorganic layer on the second conductive pattern in the display area and forming an inorganic pad layer on the second pad layer in the pad area; and
patterning an organic layer on the inorganic layer in the display area,
wherein the inorganic layer includes a first inorganic layer having a first refractive index and a second inorganic layer having a second refractive index less than the first refractive index.

17. The method according to claim 16, wherein the inorganic layer is deposited through a chemical vapor deposition (CVD) process.

18. The method according to claim 16, wherein a refractive index of the organic layer is less than the second refractive index.

19. The method according to claim 18, wherein the organic layer is a reflection adjust layer or a color filter layer.

20. The method according to claim 16, further comprising:
removing the pad inorganic layer in the pad area by using the organic layer as an etching mask.
